(19) United States
(12) Patent Application Publication
(10) Pub. No.: US 2026/0144163 A1
(43) Pub. Date: May 21, 2026

(54) THREE-DIMENSION SEMICONDUCTOR DEVICE

(71) Applicant: WHALECHIP CO., LTD., Taipei City (TW)

(72) Inventors: Ya-Tung TSAI, Taipei City (TW); Huey-Jen LIM, Taipei City (TW); Ching-Huang HUNG, Taipei City (TW)

(21) Appl. No.: 19/393,588

(22) Filed: Nov. 19, 2025

(30) Foreign Application Priority Data
Nov. 20, 2024 (CN) 2024116595947
Jan. 20, 2025 (CN) 2025100836011

(51) Int. Cl. H10W 90/26; H03K 19/17728; H03K 19/17736; H03K 19/1776; H10B 80/00; H10D 80/30

(52) U.S. Cl. CPC H10W 90/26; H03K 19/17728; H03K 19/17744; H03K 19/1776; H10B 80/00; H10D 80/30; H10W 44/234; H10W 72/234; H10W 90/722

(57) ABSTRACT

The present disclosure is related to a three-dimension semiconductor device comprising a first circuit layer and a second circuit layer. The first circuit layer comprises a first circuit block. The second circuit layer is disposed on the first circuit layer and comprises a second circuit block. The first circuit block and the second circuit block establish an electrical connection relationship through connecting pillars. By increasing the wiring dimension of the wiring, the present disclosure allows the first circuit block and the second circuit block, which were originally only electrically connected in two dimensions, to establish electrical connections through the third dimension. Therefore, the length of a signal transmission path is reduced. The purpose of reducing wiring length and signal delay is achieved.

### CROSS-REFERENCE TO RELATED APPLICATION

This non-provisional application claims priority under 35 U.S.C. § 119(a) to Chinese Patent Application Serial Number 2024116595947, filed on Nov. 20, 2024, and Chinese Patent Application Serial Number 2025100836011, filed on Jan. 20, 2025, the entire contents of which are hereby incorporated by reference.

### BACKGROUND OF THE INVENTION

### Technical Field

The present disclosure relates to a semiconductor device, and more particularly, to a three-dimension semiconductor device.

### Prior Art

As the computational demands of electronic devices continue to increase, the number of circuit blocks incorporated within such devices also increases accordingly, leading to greater wiring complexity and density, and consequently, longer routing paths and increased signal delays.

To enhance the performance of chip devices without increasing their physical volume or footprint, three-dimensional (3D) packaging manufacturing processes that integrate bare dies fabricated by different manufacturing processes and having different material or electrical properties have been developed, such as Wafer-on-Wafer (WoW), Chip-on-Wafer-on-Substrate (CoWoS), and System-on-Integrated-Chips (SoIC) processes.

### SUMMARY OF THE INVENTION

The present disclosure is related to a three-dimension semiconductor device, which includes a first circuit layer and a second circuit layer. The first circuit layer includes a first switch block. The second circuit layer is disposed on the first circuit layer and includes a second switch block. The second switch block and the first switch block are electrically connected via a connecting pillar. The vertical projections of the second switch block, the first switch block, and the connecting pillar at least partially overlap on the first circuit layer.

The present disclosure is related to a three-dimension semiconductor device, which includes a first circuit layer and a second circuit layer. The first circuit layer includes configuration memory. The second circuit layer is disposed on the first circuit layer. the second circuit layer includes a circuit block. The circuit block is electrically connected to the configuration memory. The configuration memory and the circuit block are in different circuit layers.

The present disclosure is related to a three-dimension semiconductor device, which includes a first circuit layer and a second circuit layer. The first circuit layer is disposed on the second circuit layer. The three-dimensional semiconductor device includes a first logic circuit, a first transmitter, and a first receiver. The first logic circuit is disposed in the first circuit layer. The first transmitter is disposed in the first circuit layer, electrically connected to the first logic circuit, configured to receive a first digital signal from the first logic circuit and output a first analog signal to the second circuit layer. The first receiver is disposed in the first circuit layer, electrically connected to the first logic circuit, and configured to receive a second analog signal from the second circuit layer and convert the second analog signal into a second digital signal. The second digital signal is transmitted to the first logic circuit. The first analog signal and the second analog signal are both high-frequency analog signals.

### BRIEF DESCRIPTION OF DRAWINGS

FIG. 1 is a schematic diagram of an embodiment of the three-dimension semiconductor device according to an embodiment of the present disclosure.

FIG. 2 is a schematic diagram of a second embodiment of the three-dimension semiconductor device according to an embodiment of the present disclosure.

FIG. 3 is a schematic diagram of a third embodiment of the three-dimension semiconductor device according to an embodiment of the present disclosure.

FIG. 4 is a schematic diagram of an embodiment of a topology of a switch block according to an embodiment of the present disclosure.

FIG. 5 is a schematic diagram of a second embodiment a topology of a switch block according to an embodiment of the present disclosure.

FIG. 6 is a schematic diagram of a third embodiment a topology of a switch block according to an embodiment of the present disclosure.

FIG. 7 is a schematic diagram of a combined embodiment of a switch block according to an embodiment of the present disclosure.

FIG. 8 is a schematic diagram of a fourth embodiment of the three-dimension semiconductor device according to an embodiment of the present disclosure.

FIG. 9 is a schematic diagram of an embodiment of a transmitter according to an embodiment of the present disclosure.

FIG. 10 is a schematic diagram of an embodiment of a receiver according to an embodiment of the present disclosure.

FIG. 11 is a schematic diagram of another embodiment of a receiver according to an embodiment of the present disclosure.

FIG. 12 is a schematic diagram of a fifth embodiment of the three-dimension semiconductor device according to an embodiment of the present disclosure.

FIG. 13 is a schematic diagram of a sixth embodiment of the three-dimension semiconductor device according to an embodiment of the present disclosure.

FIG. 14 a schematic diagram of a seventh embodiment of the three-dimension semiconductor device according to an embodiment of the present disclosure.

FIG. 15 a schematic diagram of an eighth embodiment of the three-dimension semiconductor device according to an embodiment of the present disclosure.

FIG. 16 a schematic diagram of a ninth embodiment of the three-dimension semiconductor device according to an embodiment of the present disclosure.

### DETAILED DESCRIPTION OF THE INVENTION

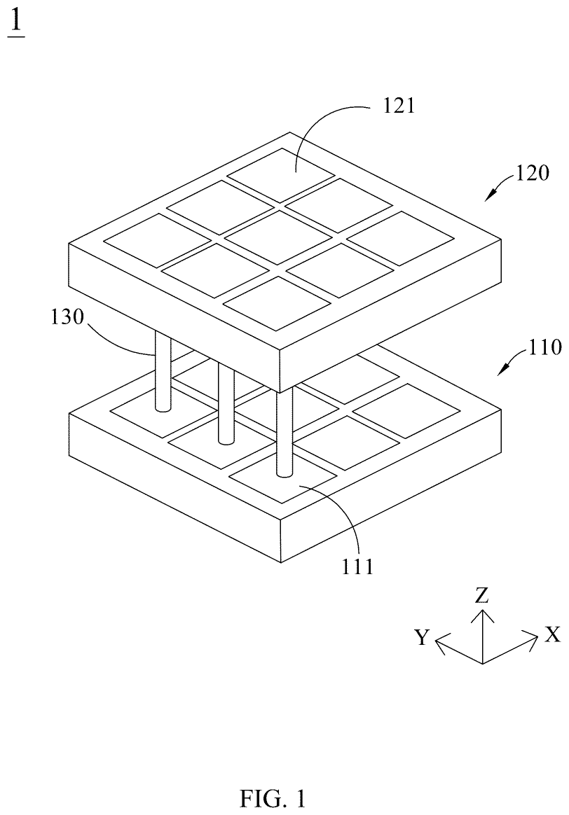

Please refer to FIG. 1, FIG. 1 is a schematic diagram of an embodiment of the three-dimension semiconductor device according to an embodiment of the present disclosure. The three-dimensional semiconductor device 1 includes a first circuit layer 110 and a second circuit layer 120. The three-dimensional semiconductor device 1 may be implemented by packaging manufacturing processes such as WoW, CoWoS, or SoIC. In one embodiment, the first circuit layer 110 and the second circuit layer 120 are field-programmable gate arrays. The first circuit layer 110 and the second circuit layer 120 may be implemented by dies.

The first circuit layer 110 includes a configuration memory 111. The configuration memory 111 is arranged on the first circuit layer 110 along a first axis X and a second axis Y. The configuration memory 111 is configured to store a look-up table (LUT) of a corresponding logic block (such as a configurable Logic Block (CLB)). In the embodiment, the configuration memory 111 is, for example, a static random-access memory (SRAM).

The second circuit layer 120 is disposed on the first circuit layer 110. The second circuit layer 120 includes a circuit block 121. The circuit block 121 is arranged on the second circuit layer 120 along the first axis X and the second axis Y. The circuit block 121 is, for example, a logic block. A logic block is, for example, a circuit block that contains multiplexers, shift registers, and logic gates. The circuit block 121 establishes an electrical connection in a third axis Z with the corresponding configuration memory 111 via at least one connecting pillar 130. The first axis X is perpendicular to the second axis Y, and the third axis Z is perpendicular to both the first axis X and the second axis Y. The connecting pillar 130 may be implemented by a hybrid bonding technology. The hybrid bonding may also be called as a direct bond interconnect (DBI). For example, two chips (such as the first circuit layer 110 and the second circuit layer 120) are covered with a dielectric material such as silicon dioxide (SiO2), the dielectric material is embedded in copper contacts connected to the chips, the contacts of the two chips are then brought face to face, and then the copper contacts of the two chips are heated and expanded to connect through heat treatment. Thus, the pillars are formed between the two chips. In one embodiment, the second circuit layer 120 may further include circuit blocks implemented as digital signal processor (DSP) blocks, memory blocks, Hardened IP, connection blocks, and/or switch blocks.

By establishing a signal transmission path in the third axis Z via at least one connecting pillar 130 between each configuration memory 111 and the corresponding circuit block 121, the circuit block 121 may read the lookup table in the configuration memory 111 to implement the expected logical function based on the lookup table. In the embodiment, there are multiple connecting pillars 130, and each circuit block 121 only reads the lookup table of the corresponding configuration memory 111.

In the embodiment, the configuration memory 111 and the circuit block 121 are located in different circuit layers, and the circuit block 121 does not include a lookup table. Compared to configuring the configuration memory 111 within the circuit block 121, by making an array of the configuration memory 111 independent of the circuit block 121 and configuring it on a different circuit layer, the array of the configuration memory 111 array is not limited by the electronic components in the circuit block 121 and may be configured more compactly. Thus, the high-density characteristics of a static random access memory may be effectively utilized to cause the array of the configuration memory 111 has a smaller area, thereby the overall area and wiring length of the array of the configuration memory 111 are effectively reduced. Meanwhile, once the three-dimension semiconductor device 1 has completed programming, it will remain in the read state, which causes the three-dimension semiconductor device 1 have a high read tolerance and is suitable for wiring implemented with hybrid bonding. Furthermore, the signal transmission capability of hybrid bonding wiring allows the three-dimension semiconductor device 1 to transmit signals at a higher read frequency. Even if the transmission load of hybrid bonding wiring increases, it will not affect the read capability of the configuration memory 111.

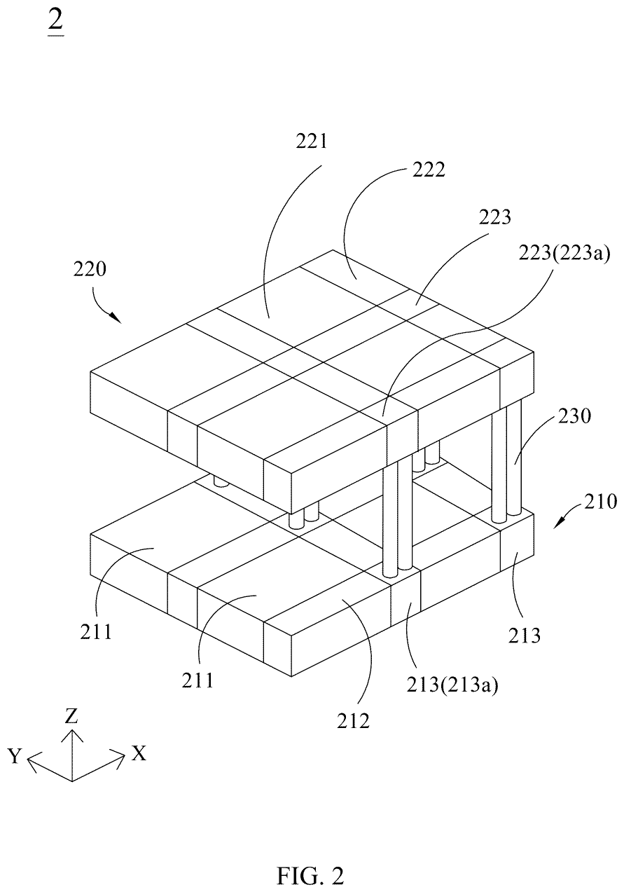

Please refer to FIG. 2, FIG. 2 is a schematic diagram of a second embodiment of the three-dimension semiconductor device according to an embodiment of the present disclosure. The three-dimensional semiconductor device 2 includes a first circuit layer 210 and a second circuit layer 220. The first circuit layer 210 includes a plurality of first circuit blocks 211, a plurality of first connection areas 212, and a plurality of first switch blocks 213. The plurality of first circuit blocks 211 and the plurality of first connection areas 212 are arranged alternately. Each first circuit block 211 is electrically connected to the at least one first switch block 213 via a wiring of the at least one adjacent first connection area 212, so as to establish a two-dimensional electrical connection between the multiple first circuit blocks 211 via the electrically connected first switch blocks 213. The first switch block 213 is, for example, a circuit block that includes logic circuits and/or memory. The second circuit layer 220 is disposed on the first circuit layer 210. The second circuit layer 220 includes a plurality of second circuit blocks 221, a plurality of second connection areas 222, and a plurality of second switch blocks 223. The second switch block 223 of the second circuit layer 220 is connected to the first switch block 213 of the first circuit layer 210 via a connecting pillar 230. The second switch block 223 is, for example, a circuit block that includes logic circuits and/or memory.

Vertical projections of the first switch block 213 and the second switch block 223 connected by the connecting pillar 230 on the first circuit layer 210 at least partially overlap. For example, a second switch block 223a of the second circuit layer 220 is connected to a first switch block 213a of the first circuit layer 210 via the connecting pillar 230, and the vertical projections (on the third axis Z) of the first switch block 213a and the second switch block 223a on the first circuit layer 210 overlap. Thus, the first switch block 213 of the first circuit block 211 and the second switch block 223 of the second circuit layer 220 may individually achieve signal transmission in a two-dimensional plane (the first axis X and the second axis Y) through the wirings of the first connection area 212 and the second connection area 222, and may implement a signal transmission in the third dimension (third axis Z) between the first switch block 213 and the second switch block 223 via the connecting pillar 230. Therefore, a wiring length between the first switch block 213 and the second switch block 223 is effectively reduced, thereby reducing the signal delay caused by the wiring length. The purposes of reducing wiring length and signal delay are achieved, while increasing the flexibility and convenience of wiring design.

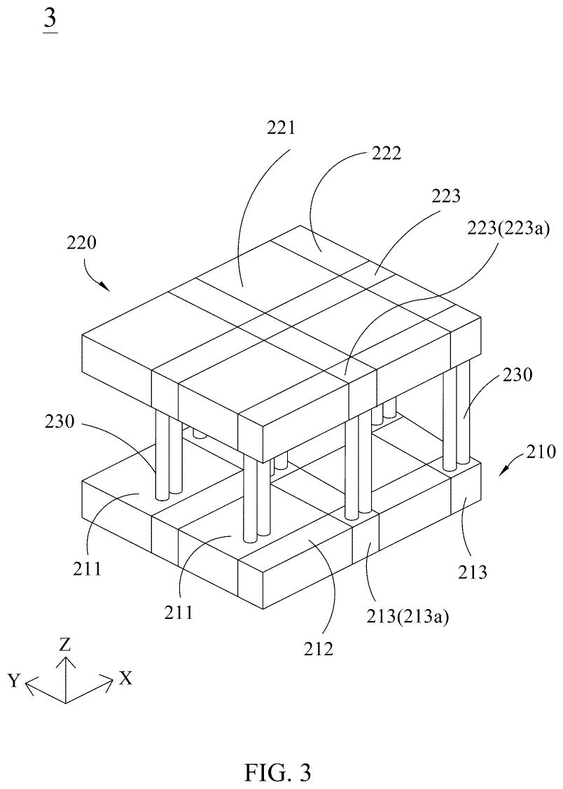

In one embodiment, the first circuit block 211 and the second circuit block 221 may be implemented by a logic block, a digital signal processor (DSP) block, a memory block and/or a Harden IP. In one embodiment, the first circuit block 211 and the second circuit block 221 may be the same or different. For example, the first circuit block 211 is a logic block, and the second circuit block 221 is a combination of a logic block and a memory block. In one embodiment, the first circuit block 211 may be implemented by a circuit including a configuration memory and a first logical block, and the second circuit block 221 may be implemented by a circuit including a second logical block. The second logical block of the second circuit block 221 is electrically connected to the configuration memory of the first circuit block 211 via the at least one connecting pillar 230 (as shown in a three-dimension semiconductor device 3 in FIG. 3). The configuration memory stores lookup tables corresponding to the second logical block. That is, the second circuit block 221 does not have a configuration memory for the second logical block. In this way, the configuration memory and the second logical block may establish a signal transmission along the third axis Z. In other embodiment, the memory of the plurality of second connection areas 222 and the plurality of second switch blocks 223 of the second circuit layer 220 may also be implemented in the first circuit block 211. By centrally configuring memory components (such as the configuration memory and/or memory) on a single circuit layer (such as the first circuit layer 210), the design flexibility of the first circuit layer 210 and the second circuit layer 220 may be further improved. The first circuit block 211 and the second circuit block 221 may also establish a signal transmission in the third axis Z via the first switch block 213 and the second switch block 223 according to design requirements. Therefore, the first circuit layer 210 and the second circuit layer 220 may be configured with different functional circuit blocks according to different needs, so as to optimize the wiring according to the design requirements. Accordingly, the wiring feasibility is improved, and the signal delay caused by the wiring length is reduced, thus achieving the purpose of reducing the wiring length and the signal delay. In one embodiment, the manufacturing processes of the first circuit block 211 and the second circuit block 221 may be the same or different. For example, the first circuit block 211 may be implemented using a 5 nm (nanometer) manufacturing process, and the second circuit block 221 can be implemented using a 5 nm or 3 nm manufacturing process. The first circuit block 211 and the second circuit block 221 may implement by the appropriate manufacturing process according to product requirements. Thus, the manufacturing cost of the three-dimensional semiconductor device may be reduced.

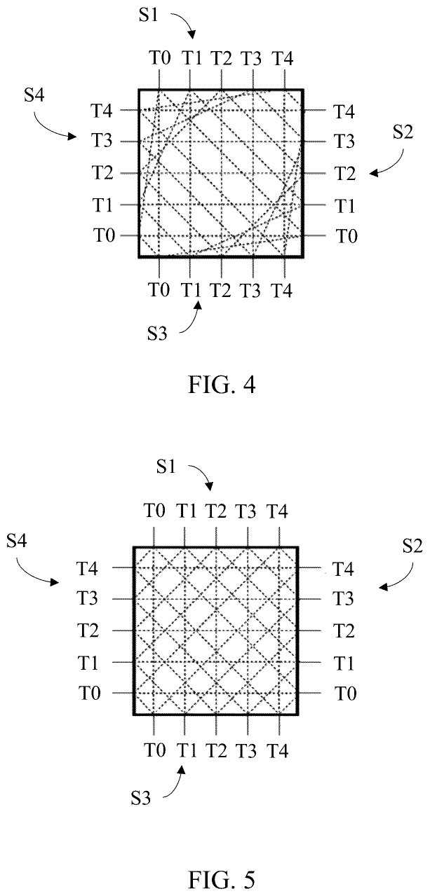

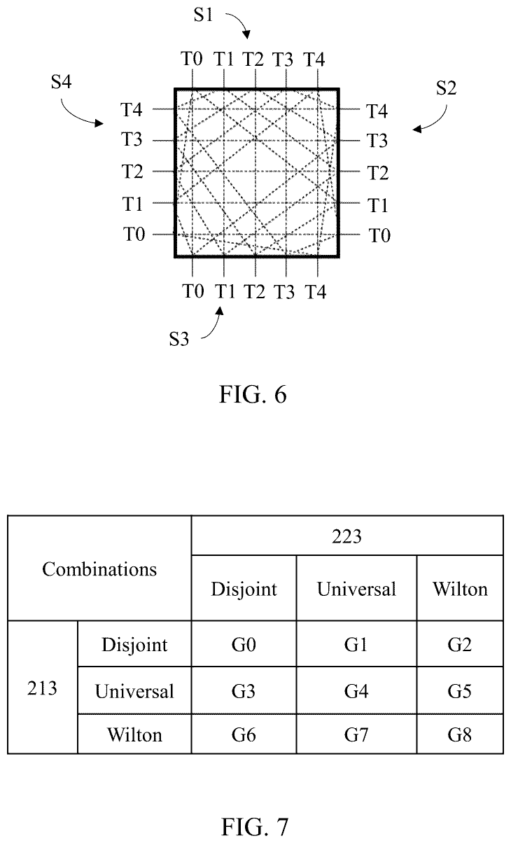

Please refer to FIG. 4 to FIG. 7. FIG. 4 is a schematic diagram of a Disjoint topology of a switch block. FIG. 5 is a schematic diagram of a Universal topology of a switch block. FIG. 6 is a schematic diagram of a Wilton topology of a switch block. FIG. 7 is a schematic diagram of a combined embodiment of a switch block. In FIGS. 4-6, each switch block may be defined as having a first side S1, a second side S2, a third side S3, and a fourth side S4. Each side of the switch block has connecting terminals T0 to T4. The connecting terminals T0 to T4 on different sides are connected via a switch unit. The switching blocks in different topologies have different connection structures. For example, in the embodiment of FIG. 4, the connecting terminal T0 of the first side S1 of the switch block is individually connected to the connecting terminals T0 of the second side S2, the third side S3 and the fourth side S4. In the embodiment shown in FIG. 5, the connecting terminal T0 of the first side S1 of the switch block is individually connected to the connecting terminal T0 of the second side S2, the connecting terminal T0 of the third side S3, and the connecting terminal T4 of the fourth side S4. In the embodiment shown in FIG. 6, the connecting terminal T0 of the first side S1 of the switch block is individually connected to the connecting terminal T1 of the second side S2, the connecting terminal T0 of the third side S3, and the connecting terminal T0 of the fourth side S4. In the embodiment, the connecting terminals T0 to T4 of the two switch blocks (such as the first switch block 213 and the second switch block 223) located on the same side are connected through the connecting pillar 230. For example, the connecting terminal T0 of the first side S1 of the first switch block 213 is connected to the connecting terminal T0 of the first side S1 of the second switch block 223 via the connecting pillar 230. Thus, the first switch block 213 and the second switch block 223 may establish the signal transmission in the third dimension via the connecting pillar 230. In one embodiment, the topology of the first switch block 213 is the same as or different from the topology of the second switch block 223. For example, the topology of the first switch block 213 is the Universal topology, while the topology of the second switch block 223 may be the Universal topology or the Wilton topology. Therefore, as shown in FIG. 7, the combination between the first switch block 213 and the second switch block 223 may be implemented through at least nine topological combinations (G0˜G8). This increases the flexibility in switch block configuration and overall circuit design.

One embodiment of the three-dimension semiconductor device of the present disclosure may effectively reduce the area and wiring required for the configuration memory by centrally setting the configuration memory of the logic blocks on an independent circuit layer and implement the signal transmission between the logic block and the configuration memory in the third dimension through the connecting pillar. Furthermore, one embodiment of the three-dimension semiconductor device of the present disclosure may implement the signal transmission in the third dimension by allowing switching blocks located on different circuit layers to be connected by pillars, which may effectively reduce the wiring length between switching blocks on different circuit layers. Therefore, the embodiment of the present disclosure may reduce the wiring length and the signal delay.

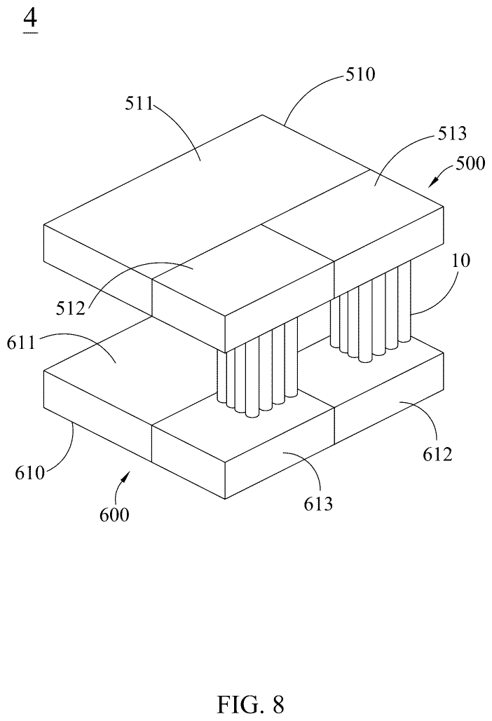

Please refer to FIG. 8. FIG. 8 is a schematic diagram of a fourth embodiment of the three-dimension semiconductor device according to an embodiment of the present disclosure. The three-dimensional semiconductor device 4 has a first circuit layer 500 and a second circuit layer 600. The first circuit layer 500 is disposed on the second circuit layer 600. That is, the first circuit layer 500 is stacked on top of the second circuit layer 600. The first circuit layer 500 and the second circuit layer 600 are electrically connected via at least two connecting pillars 10. The first circuit layer 500 and the second circuit layer 600 may configured with one or more electronic components or assemblies. In the embodiment, the connecting pillars 10 may be implemented by the aforementioned connecting pillars 230.

The first circuit layer 500 includes a logic circuit group 510. The logic circuit group 510 includes a first logic circuit 511, a first transmitter 512, and a first receiver 513. The first logic circuit 511 is, for example, a single-chip system (SoC), a field-programmable gate array (FPGA), a memory, or other logic circuit or memory circuit, and the present disclosure is not limited thereto. The first transmitter 512 is electrically connected to the first logic circuit 511 and the connecting pillars 10. The first transmitter 512 receives a first digital signal, which is from the first logic circuit 511 and transmitted in parallel transmission. The first transmitter 512 is configured to convert the first digital signal into a first analog signal for serial transmission. The first transmitter 512 transmits the first analog signal to the second circuit layer 600 via the connecting pillars 10. The first receiver 513 is electrically connected to the first logic circuit 511 and the connecting pillars 10. The first receiver 513 receives a second analog signal, which is from the second circuit layer 600 via the connecting pillars 10 and transmitted in serial transmission. The first receiver 513 is configured to convert the second analog signal into a second digital signal for parallel transmission, and transmits the second digital signal to the first logic circuit 511.

The second circuit layer 600 includes a logic circuit group 610. The logic circuit group 610 includes a second logic circuit 611, a second transmitter 612, and a second receiver 613. The second logic circuit 611 is, for example, a single-chip system (SoC), a field-programmable gate array (FPGA), a memory, or other logic circuit or memory circuit, and the present disclosure is not limited thereto. The second transmitter 612 is electrically connected to the second logic circuit 611. The second transmitter 612 is connected to the first receiver 513 via the connecting pillars 10. The second transmitter 612 receives the second digital signal from the second logic circuit 611. The second transmitter 612 is configured to convert the second digital signal into a second analog signal and transmit the second analog signal to the connecting pillars 10. The second receiver 613 is electrically connected to the second logic circuit 611. The second receiver 613 is connected to the first transmitter 512 via the connecting pillar 10. The second receiver 613 is configured to receive the first analog signal from the first transmitter 512. The second receiver 613 is configured to convert the first analog signal into a first digital signal and transmit the first digital signal to the second logic circuit 611. The first digital signal and the second digital signal include multiple digital signals transmitted in parallel transmission, and the first analog signal and the second analog signal include multiple analog signals transmitted in serial transmission.

Thus, the three-dimensional semiconductor device of the present disclosure may complete the digital-to-analog signal conversion and analog signal transmission between the first logic circuit 511 and the second logic circuit 611 through the first transmitter 512, the first receiver 513, the second transmitter 612, and the second receiver 613. In the embodiment, the first analog signal and the second analog signal are high-frequency analog signals. In one embodiment, the transmission rate of the high-frequency analog signal is equal to or greater than 2.5 GT/s (Gigabits per second), and the present disclosure is not limited thereto. In one embodiment, the first analog signal and the second analog signal are Low Voltage Differential Signals (LVDS).

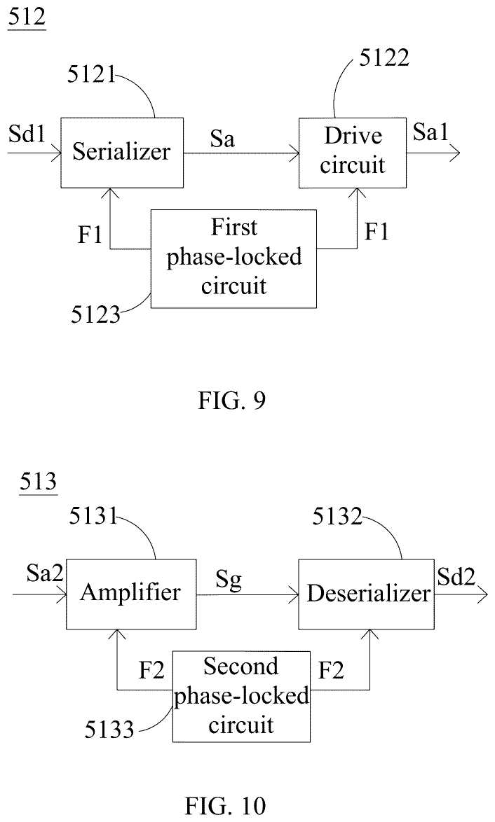

Please refer to FIGS. 8 and 9, FIG. 9 is a schematic diagram of an embodiment of the transmitter of the present disclosure. FIG. 9 is illustrated using the first transmitter 512 as an example. The first transmitter 512 includes a serializer 5121, a drive circuit 5122, and a first phase-locked circuit 5123. The first phase-locked circuit 5123 is electrically connected to the serializer 5121 and the drive circuit 5122 to generate a first frequency F1 required for the operation of the first transmitter 512. The serializer 5121 is electrically connected to the first logic circuit 511, the drive circuit 5122, and the first phase-locked circuit 5123. In one embodiment, the drive circuit 5122 is a Low Voltage Differential Signal drive circuit. The serializer 5121 receives a first digital signal Sd1 from the first logic circuit 511 and converts the first digital signal Sd1 into an initial analog signal Sa for serial transmission based on a first frequency F1. The drive circuit 5122 is electrically connected to the serializer 5121, the first phase-locked circuit 5123, and the connecting pillars 10. The drive circuit 5122 outputs the first analog signal Sa1. In one embodiment, the drive circuit 5122 may be implemented by a transmitter driver. The drive circuit 5122 is configured to receive the initial analog signal Sa and output the initial analog signal Sa as the first analog signal Sa1 based on the first frequency F1. In the embodiment, the architecture and operation of the second transmitter 612 are the same as those of the first transmitter 512, so they will not be described again here.

Please refer to FIG. 8 and FIG. 10. FIG. 10 is a schematic diagram of an embodiment of a receiver of the present disclosure. FIG. 10 is illustrated using the first receiver 513 as an example. The first receiver 513 includes an amplifier 5131 and a deserializer 5132. The amplifier 5131 is electrically connected to the connecting pillars 10 and the deserializer 5132. In one embodiment, the amplifier 5131 may be implemented by an amplifier circuit. In one embodiment, the amplifier 5131 is a Low Voltage Differential Signal amplifier. The amplifier 5131 receives the second analog signal Sa2 via the connecting pillars 10 and amplifies the second analog signal Sa2 to generate an amplified analog signal Sg. The deserializer 5132 is electrically connected to the amplifier 5131 and the first logic circuit 511. The deserializer 5132 is configured to receive the amplified analog signal Sg and convert it into a second digital signal Sd2 that is output in parallel transmission. The second digital signal Sd2 is configured to transmit to the first logic circuit 511. In one embodiment, the deserializer 5132 converts the amplified analog signal Sg into a second digital signal Sd2 based on the signal frequency of the amplified analog signal Sg. In one embodiment, the first receiver 513 may include a second phase-locked loop 5133. The second phase-locked loop 5133 is electrically connected to the amplifier 5131 and the deserializer 5132 to generate the second frequency F2. The amplifier 5131 and the deserializer 5132 may perform the above-mentioned amplification and deserialization operations based on the second frequency F2. In the embodiment, the architecture and operation of the second receiver 613 are the same as those of the first receiver 513, so they will not be described again here.

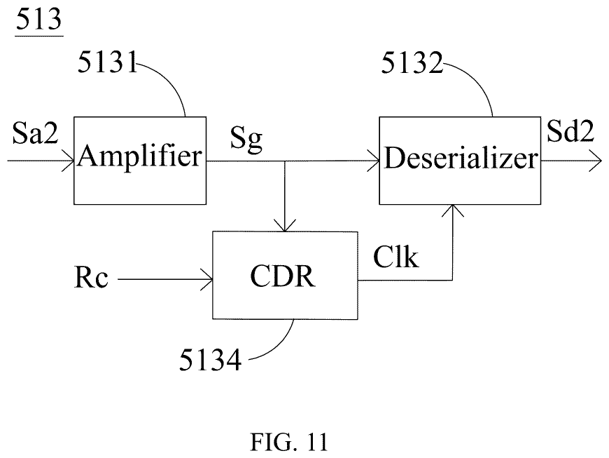

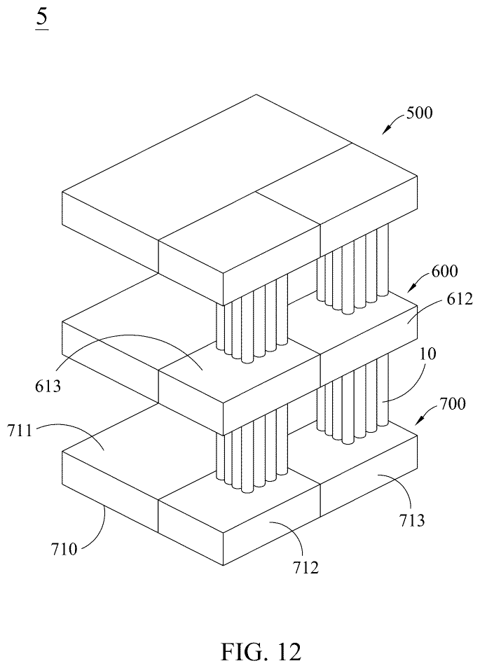

Please refer to FIG. 8 and FIG. 11. FIG. 11 is a schematic diagram of another embodiment of a receiver of the present disclosure. FIG. 11 is illustrated using the first receiver 513 as an example. The difference between FIG. 11 and FIG. 10 is that FIG. 11 includes a Clock Data Recovery (CDR) circuit 5134. The clock data recovery circuit 5134 is electrically connected to the amplifier 5131 and the deserializer 5132 to receive the amplified analog signal Sg output by the amplifier 5131. The clock data recovery circuit 5134 receives a reference clock signal Rc, which may be generated by the first receiver 513 or come from an external circuit. The clock data recovery 5134 circuit is configured to extract serial data from the received amplified analog signal Sg based on the reference clock signal Rc and an amplified analog signal Sg, and to recover a clock signal Clk corresponding to the serial data. Therefore, the deserializer 5132 may correctly restore the analog signal to a digital signal using the corresponding clock signal Clk. In the embodiment, the architecture and operation of the second receiver 613 are the same as those of the first receiver 513, so they will not be described again here.

Therefore, the three-dimension semiconductor device embodiment of the present disclosure realizes signal transmission between logic circuits by setting up a transmitter and a receiver to transmit analog signals at high frequency. That is, the first logic circuit and the second logic circuit do not transmit signals directly using high-frequency digital signals, but instead transmit signals using analog signals that may be transmitted at high frequencies. Therefore, the present disclosure uses analog signals to achieve high-frequency signal transmission, making the high-frequency transmitted signals less susceptible to electromagnetic interference and effectively preserving the integrity of the high-frequency signals. Meanwhile, by using serial transmission, the present disclosure may meet the needs of massive transmission with a limited number of connection points, thereby improving the signal transmission efficiency of the three-dimensional semiconductor device.

Please refer to FIG. 12, which is a schematic diagram of another embodiment of the three-dimension semiconductor device of the present disclosure. In the embodiment of FIG. 12, the three-dimensional semiconductor device 5 further includes a third circuit layer 700. The third circuit layer 700 is located below the second circuit layer 600. That is, the first circuit layer 500, the second circuit layer 600, and the third circuit layer 700 are stacked on top of each other. The third circuit layer 700 is electrically connected to the second circuit layer 600 via at least one connecting pillar 10. The third circuit layer 700 is provided with one or more electronic components or assemblies.

The third circuit layer 700 includes a logic circuit group 710. The logic circuit group 710 includes a third logic circuit 711, a third transmitter 712, and a third receiver 713. The third logic circuit 711 is, for example, a single-chip system (SoC), a field-programmable gate array (FPGA), a memory, or other logic circuit or memory circuit, and the present disclosure is not limited thereto. The third transmitter 712 is electrically connected to the third logic circuit 711 and the connecting pillar 10. The third transmitter 712 receives the third digital signal from the third logic circuit 711. The third transmitter 712 is configured to convert the third digital signal into a third analog signal and transmit the third analog signal to the second receiver 613 via the connecting pillar 10. The third receiver 713 is electrically connected to the third logic circuit 711 and the connecting pillar 10. The third receiver 713 receives the second analog signal from the second transmitter 612 via the connecting pillars 10. The third receiver 713 is configured to convert the second analog signal into a second digital signal and transmit the second digital signal to the third logic circuit 711. In the embodiment, the architecture and operation of the third transmitter 712 are the same as those of the first transmitter 512, and therefore will not be described again. In the embodiment, the architecture and operation of the third receiver 713 are the same as those of the first receiver 513, and therefore will not be described again.

In the embodiment, the second receiver 613 may further receive a third analog signal from the third transmitter 712 via the connecting pillar 10. That is, the second receiver 613 may receive a first analog signal from the first transmitter 512 or a third analog signal from the third transmitter 712.

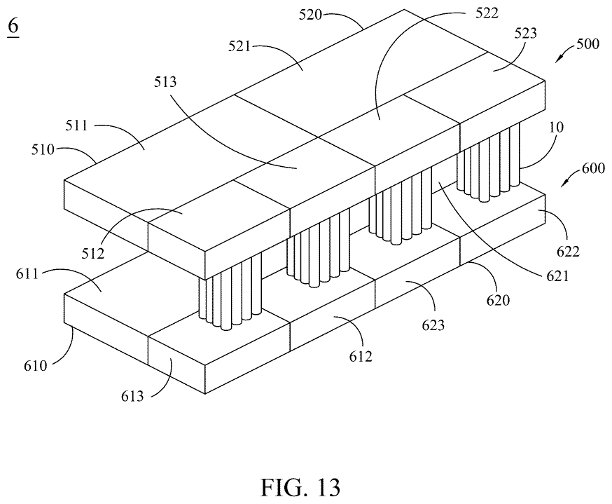

Please refer to FIG. 13, which is a schematic diagram of another embodiment of the three-dimension semiconductor device of the present disclosure. In the embodiment of FIG. 13, the first circuit layer 500 of the three-dimension semiconductor device 6 further includes a logic circuit group 520, and the second circuit layer 600 further includes a logic circuit group 620. The logic circuit group 520 includes a first logic circuit 521, a first transmitter 522, and a first receiver 523. The first logic circuit 521, the first transmitter 522, and the first receiver 523 are identical to the aforementioned first logic circuit 511, the first transmitter 512, and the first receiver 513, and therefore will not be described again here. The logic circuit group 620 includes a second logic circuit 621, a second transmitter 622, and a second receiver 623. The second logic circuit 621, the second transmitter 622, and the second receiver 623 are identical to the aforementioned second logic circuit 611, the second transmitter 612, and the second receiver 613, and therefore will not be described again here. Therefore, in the embodiment, each circuit layer may include multiple logic circuit groups, and the present disclosure is not limited thereto.

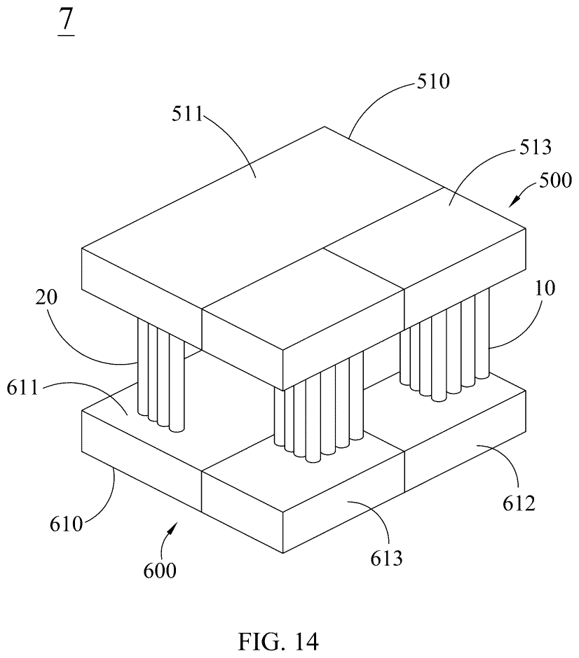

Please refer to FIG. 14, which is a schematic diagram of another embodiment of the three-dimension semiconductor device of the present disclosure. In the embodiment of FIG. 14, the first logic circuit 511 of the logic circuit group 510 and the second logic circuit 611 of the logic circuit group 610 of the three-dimensional semiconductor device 7 may exchange digital signals via at least one connecting pillar 20. In the embodiment, the first logic circuit 511 and the second logic circuit 611 are electrically connected via the connecting pillar 20. Therefore, when the first digital signal from the first logic circuit 511 and/or the second digital signal from the second logic circuit 611 are low-frequency digital signals, since the transmission of low-frequency digital signals is not affected by the connection point configuration, the digital signals between the first logic circuit 511 and the second logic circuit 611 may be transmitted via the connecting pillar 20.

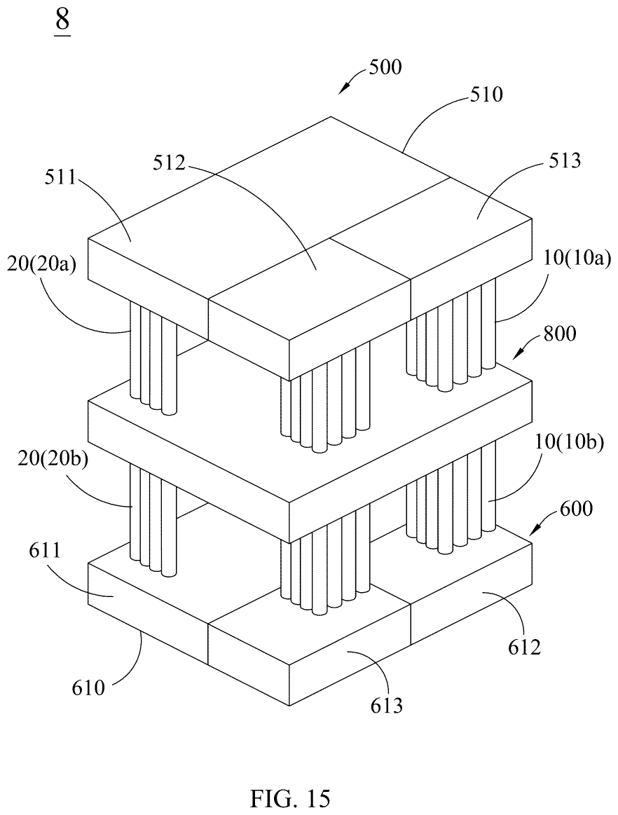

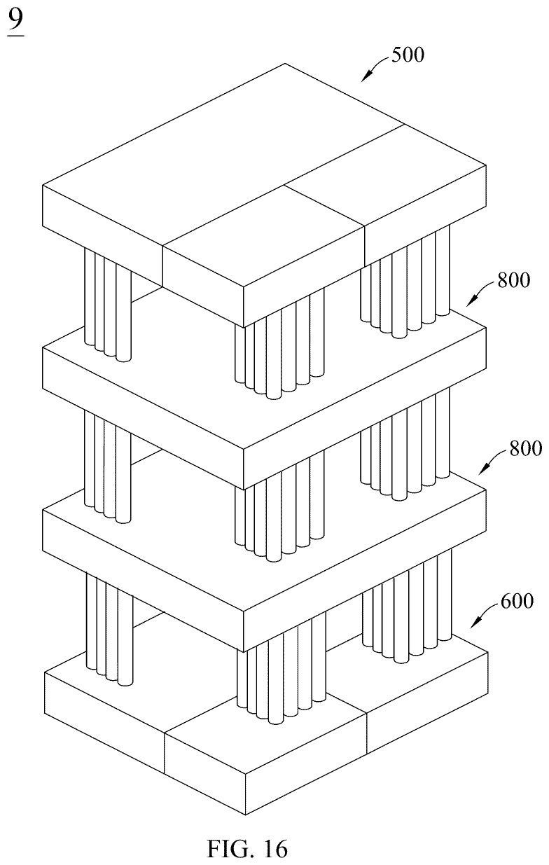

FIG. 15 is a schematic diagram of another embodiment of the three-dimension semiconductor device of this application. In the embodiment shown in FIG. 15, the logic circuit group 510 and logic circuit group 610 of the three-dimension semiconductor device 8 are electrically connected to each other via the electrical connection layer 800. The electrical connection layer 800 is disposed between the first circuit layer 500 and the second circuit layer 600. The electrical connection layer 800 is electrically connected to the first logic circuit 511, the first transmitter 512, the first receiver 513, the second logic circuit 611, the second transmitter 612, and the second receiver 613. In the embodiment, the electrical connection layer 800 may be implemented from a bare die including a metal layer and/or silicon vias. For example, the first receiver 513 is electrically connected to the silicon vias of the electrical connection layer 800 via the connecting pillar 10a, and the second transmitter 612 is electrically connected to the silicon vias of the electrical connection layer 800 via the connecting pillar 10b. In this way, the first receiver 513 and the second transmitter 612 establish a communication connection for a high-frequency analog signal via the connecting pillar 10a, the silicon vias of the electrical connection layer 800, and the connecting pillar 10b. The first logic circuit 511 is electrically connected to the electrical connection layer 800 via the connecting pillar 20a, and the second logic circuit 611 is electrically connected to the electrical connection layer 800 via the connecting pillar 20b. In this way, the first logic circuit 511 and the second logic circuit 611 establish a communication connection for low-frequency digital signals via the connecting pillar 20a, the electrical connection layer 800, and the connecting pillar 20b. In one embodiment, the first logic circuit 511 and the second logic circuit 611 may establish a communication connection via multiple electrical connection layers 800. FIG. 16 shows the three-dimension semiconductor device 9. By setting the Electrical connection layer 800, the signal transmission path may be adjusted according to requirements, thereby increasing the design flexibility of the three-dimension semiconductor device.

According to the above, the three-dimension semiconductor device embodiment of the present disclosure, by configured with a transmitter and a receiver, may realize the conversion between digital signals and analog signals, and may complete the signal transmission between logic circuits by transmitting analog signals at high frequency. It enables the transmission of high-frequency signals and makes the transmitted signals less susceptible to electromagnetic interference, effectively preserving the integrity of the high-frequency signals. By using serial transmission, the present disclosure may meet the needs of massive transmission with a limited number of connection points, effectively improving the signal transmission efficiency of the three-dimensional semiconductor device.

What is claimed is:

1. A three-dimension semiconductor device, comprising:
a first circuit layer, comprising a first switch block; and
a second circuit layer, disposed on the first circuit layer, comprising a second switch block,
wherein the second switch block and the first switch block are electrically connected via a connecting pillar, and vertical projections of the second switch block, the first switch block, and the connecting pillar at least partially overlap on the first circuit layer.

2. The three-dimension semiconductor device as claimed in claim 1, wherein a topology of the first switch block is the same as or different from a topology of the second switch block.

3. The three-dimension semiconductor device as claimed in claim 2, wherein the topology comprises a Disjoint topology, a Universa topology and a Wilton topology.

4. The three-dimension semiconductor device as claimed in claim 1, wherein the first switch block and the second switch block comprise a plurality of connecting terminals, and the plurality of connecting terminals of the first switch block is electrically connected to the plurality of connecting terminals of the second switch block via a plurality of connecting pillars.

5. The three-dimension semiconductor device as claimed in claim 4, wherein the plurality of connecting terminals of the first switch block and the plurality of connecting terminals of the second switch block located on the same side are connected via the plurality connecting pillars.

6. The three-dimension semiconductor device as claimed in claim 1, wherein the first circuit layer comprises a configuration memory and a first logical block, the second circuit layer comprises a second logical block, the second logical block is electrically connected to the configuration memory via a connecting pillar, and the configuration memory and the second logical block are in different circuit layers.

7. The three-dimension semiconductor device as claimed in claim 1, wherein the first circuit layer and the second circuit layer are implemented by a field-programmable gate array.

8. The three-dimension semiconductor device as claimed in claim 1, wherein the first circuit layer comprises a first circuit block, the second circuit layer comprises a second circuit block, and the first circuit block and the second circuit block are functional circuit blocks that are the same or different.

9. The three-dimension semiconductor device as claimed in claim 8, wherein the first circuit block and the second circuit block comprise a logic block, a digital signal processor block, a memory block, and a Harden Ip.

10. The three-dimension semiconductor device as claimed in claim 1, wherein a manufacturing process of the first circuit layer and a manufacturing process of the second circuit layer are the same or different.

11. A three-dimension semiconductor device, comprising:
a first circuit layer, comprising a configuration memory; and
a second circuit layer, disposed on the first circuit layer, comprising a circuit block electrically connected to the configuration memory;
wherein the configuration memory and the circuit block are in different circuit layers.

12. The three-dimension semiconductor device as claimed in claim 11, wherein the configuration memory stores a look-up table corresponding to the circuit block.

13. The three-dimension semiconductor device as claimed in claim 11, wherein the circuit block is a logic block.

14. The three-dimension semiconductor device as claimed in claim 11, wherein the circuit block is not configured with the configuration memory.

15. A three-dimension semiconductor device, which comprises a first circuit layer and a second circuit layer, the first circuit layer being disposed on the second circuit layer, comprising:
a first logic circuit, disposed in the first circuit layer;
a first transmitter, disposed in the first circuit layer, electrically connected to the first logic circuit, configured to receive a first digital signal from the first logic circuit and output a first analog signal to the second circuit layer; and
a first receiver, disposed in the first circuit layer, electrically connected to the first logic circuit, configured to receive a second analog signal from the second circuit layer, convert the second analog signal to a second digital signal and transmit the second digital signal to the first logic circuit;
wherein the first analog signal and the second analog signal are high-frequency analog signals.

16. The three-dimension semiconductor device as claimed in claim 15, further comprising:
a second logic circuit, disposed in the second circuit layer;
a second transmitter, disposed in the second circuit layer, electrically connected to the second logic circuit, configured to receive a second digital signal from the second logic circuit and output a second analog signal to the first circuit layer; and
a second receiver, disposed in the second circuit layer, electrically connected to the second logic circuit and the first transmitter, configured to receive the first analog signal from the first transmitter, convert the first analog signal into the first digital signal and transmit the first digital signal to the second logic circuit.

17. The three-dimension semiconductor device as claimed in claim 16, wherein the first receiver, the first transmitter, the second receiver, and the second transmitter are electrically connected via at least two connecting pillars.

18. The three-dimension semiconductor device as claimed in claim 17, further comprising:
an electrical connection layer, disposed between the first circuit layer and the second circuit layer, electrically connected to the first receiver, the first transmitter, the second receiver, and the second transmitter via the at least two connecting pillars.

19. The three-dimension semiconductor device as claimed in claim 15, wherein the first digital signal and the second digital signal comprise a plurality of digital signals transmitted in parallel transmission, and the first analog signal and the second analog signal comprise a plurality of analog signals transmitted in serial transmission.

20. The three-dimension semiconductor device as claimed in claim 15, wherein the first analog signal and the second analog signal are a Low Voltage Differential Signal.

21. The three-dimension semiconductor device as claimed in claim 15, wherein a transmission rate of the high-frequency analog signal is equal to or greater than 2.5 Gigabits per second.

22. The three-dimension semiconductor device as claimed in claim 15, wherein the first transmitter comprises:
a serializer, electrically connected to the first logic circuit, configured to receive the first digital signal and convert the first digital signal into an initial analog signal;
a drive circuit, electrically connected to the serializer, configured to receive the initial analog signal, generate the first analog signal transmitted in serial transmission based on the initial analog signal; and
a first phase-locked circuit, electrically connected to the serializer and the drive circuit, configured to generate a first frequency, which is transmitted to the serializer and the drive circuit.

23. The three-dimension semiconductor device as claimed in claim 22, wherein the first receiver comprises:
an amplifier, configured to receive the second analog signal and generate an amplified analog signal; and
a deserializer, electrically connected to the amplifier and the first logic circuit, configured to receive the amplified analog signal and convert the amplified analog signal into the second digital signal.

24. The three-dimension semiconductor device as claimed in claim 23, wherein the amplifier is a Low Voltage Differential Signal amplifier.
